(19) United States
(12) Patent Application Publication
(10) Pub. No.: US 2026/0117815 A1
(43) Pub. Date: Apr. 30, 2026

(54) ELECTRONIC DEVICE AND CONNECTION MECHANISM

(71) Applicant: Lenovo (Beijing) Limited, Beijing (CN)

(72) Inventors: Guobao JIANG, Beijing (CN); Lei WANG, Beijing (CN)

(21) Appl. No.: 19/365,663

(22) Filed: Oct. 22, 2025

(30) Foreign Application Priority Data
Oct. 31, 2024 (CN) 202411546726.5

(51) Int. Cl. F16C 11/04; H05K 5/02

(52) U.S. Cl. CPC F16C 11/04; H05K 5/0226

(57) ABSTRACT

An electronic device includes a first body, a second body, and a connection mechanism connecting the first body to the second body. The connection mechanism includes a connection body, and a rotation arm that includes a first rotation sub arm and a second rotation sub arm. The connection mechanism has a state in which the connection body, the first rotation sub arm, and the second rotation sub arm overlap along a line.

### CROSS-REFERENCE TO RELATED APPLICATION

This application claims priority to Chinese Patent Application No. 202411546726.5, filed on October 31, 2024, the entire content of which is incorporated herein by reference.

### TECHNICAL FIELD

The present disclosure generally relates to the field of electronic device technologies and, more particularly, to an electronic device and a connection mechanism.

### BACKGROUND

A foldable electronic device can be unfolded to a flat state or folded to a closed state. When the electronic device is in the flat state, a display screen of the electronic device is in a full-screen display state, which can provide a better visual experience for a user. When the electronic device is in the closed state, the electronic device has a smaller volume.

At present, as electronic devices are becoming more and more miniaturized, shells of electronic devices are becoming thinner and thinner, and a width of a connection mechanism located between two shells of an electronic device for connecting the two shells is getting smaller and smaller. However, a smaller width of the connection mechanism results in that an accommodation space formed by the connection mechanism for a deformed portion of a flexible screen when the electronic device is in the closed state cannot meet the needs.

### SUMMARY

In accordance with the disclosure, there is provided an electronic device including a first body, a second body, and a connection mechanism connecting the first body to the second body. The connection mechanism includes a connection body, and a rotation arm that includes a first rotation sub arm and a second rotation sub arm. The connection mechanism has a state in which the connection body, the first rotation sub arm, and the second rotation sub arm overlap along a line.

Also in accordance with the disclosure, there is provided a connection mechanism including a connection body, and a rotation arm that includes a first rotation sub arm and a second rotation sub arm. The connection mechanism has a state in which the connection body, the first rotation sub arm, and the second rotation sub arm overlap in a direction.

### BRIEF DESCRIPTION OF THE DRAWINGS

To more clearly illustrate the technical solutions of the embodiments of the present disclosure, the drawings needed for use in the description of the embodiments will be briefly introduced below. The drawings described below are some embodiments of the present disclosure. For those of ordinary skill in the art, other drawings can be obtained according to these drawings without any creative work. Throughout the drawings, the same or similar reference numerals represent the same or similar elements. It should be understood that the drawings are schematic and that the originals and elements are not necessarily drawn to scale.

FIG. 1 is a schematic structural diagram showing a first state of a connection mechanism of an electronic device consistent with embodiments of the present disclosure.

FIG. 2 is a schematic structural diagram showing a second state of a connection mechanism of an electronic device.

FIG. 3 is another schematic structural diagram showing a first state of a connection mechanism of an electronic device.

FIG. 4 is another schematic structural diagram showing a second state of a connection mechanism of an electronic device.

FIG. 5 is a schematic structural diagram of an electronic device in a first attitude consistent with embodiments of the present disclosure.

FIG. 6 is another schematic structural diagram of an electronic device in a first attitude consistent with embodiments of the present disclosure.

FIG. 7 is an enlarged view of part a in FIG. 6.

FIG. 8 is another schematic structural diagram of an electronic device in a first attitude consistent with embodiments of the present disclosure.

FIG. 9 is an enlarged view of a part b in FIG. 8.

FIG. 10 is a cross-sectional view of an electronic device in a second attitude consistent with embodiments of the present disclosure.

FIG. 11 is a schematic structural diagram of an electronic device in a second attitude consistent with embodiments of the present disclosure.

FIG. 12 is an enlarged view of part c in FIG. 11.

Reference numerals:

1 - Connection body; 11 - First arcuate groove; 111 - First stopper; 112 - First track groove; 12 - Second arcuate groove; 121 - Third stopper; 122 - Third track groove; 21 - First rotation sub arm; 211 - Second limit groove; 212 - Second movable member; 22 - Second rotation sub arm; 221 - First limit groove; 222 - Second stopper; 223 - First movable member; 224 - Second track groove; 23 - Third rotation sub arm; 231 - Fourth limit groove; 232 - Fourth movable member; 24 - Fourth rotation sub arm; 241 - Third limit groove; 242 - Fourth stopper; 243 - Third movable member; 244 - Fourth track groove; 31 - First plate; 32 - Second plate; 321 - Fifth movable member; 322 - Slide groove; 41 - First fixation arm; 42 - Second fixation arm; 421 - Fifth track groove; 51 - First torque arm; 511 - First gear; 512 - Second cam; 513 - Fourth cam; 52 - Second torque arm; 521 - Second gear; 522 - Guide column; 61 - First rotation shaft; 62 - Second rotation shaft; 71 - Third gear; 72 - Fourth gear; 81 - Movable member; 811 - First cam; 82 - Elastic member; 83 - First connection seat; 84 - Second connection seat; 85 - Fixing member; 851 - Third cam; 86 - Positioning member.

### DETAILED DESCRIPTION OF THE EMBODIMENTS

Various schemes and features of the present disclosure are described herein with reference to the accompanying drawings. The described embodiments are only some of the embodiments of the present disclosure, rather than all of the embodiments. Those skilled in the art can make various variations and modifications based on the concept of the present disclosure, and these variations and modifications shall fall within the scope of the present disclosure.

The terms used in the present disclosure are only for explaining the specific embodiments of the present disclosure and are not intended to limit the scope of the present disclosure. It is understandable to those skilled in the art that with the development of technology and the emergence of new scenarios, the technical solutions provided in the embodiments of the present disclosure are also applicable to similar technical problems.

The terms “first/second/third” involved in the present disclosure are only used to distinguish similar objects, and do not represent a specific order for the objects. It is understood that objects described by “first/second/third” can be interchanged with a specific order or sequence where permitted, such that the embodiments of the present disclosure described here can be implemented in an order other than that illustrated or described here. The terms “including,” “comprising,” or “having,” and any variations thereof, are intended to cover a non-exclusive inclusion, such that a process, method, system, product, or apparatus that comprises a list of elements is not necessarily limited to those elements but may include other elements not expressly listed or inherent to such process, method, product, or apparatus. Unless otherwise defined, all technical and scientific terms used in the present disclosure have the same meaning as those generally understood by those skilled in the art. The terms used in the present disclosure are only for the purpose of description and are not intended to limit the scope of the present disclosure.

The present disclosure provides an electronic device. The electronic device may be any device that includes a hinge. Any device that requires flipping is included within the scope of the present disclosure, such as laptops, foldable phones, tablets with rotating keyboards, servers, all-in-one computers, and the like.

An electronic device typically includes a first body, a second body, and a hinge mechanism connecting the first body and the second body. The hinge mechanism allows the first body and the second body to fold or unfold relative to each other. As the electronic device becomes increasingly miniaturized, the thickness of the first body and the second body of the electronic device is decreasing. When the hinge mechanism folds between the first body and the second body, the space for a screen formed by the hinge mechanism’s rotation arms changes, preventing the flexible screen from forming its predetermined shape.

In the present embodiment, the electronic device may include a first body, a second body, and a connection mechanism. The first body may be movably connected to the second body via the connection mechanism, allowing the first body and the second body to fold or unfold relative to each other.

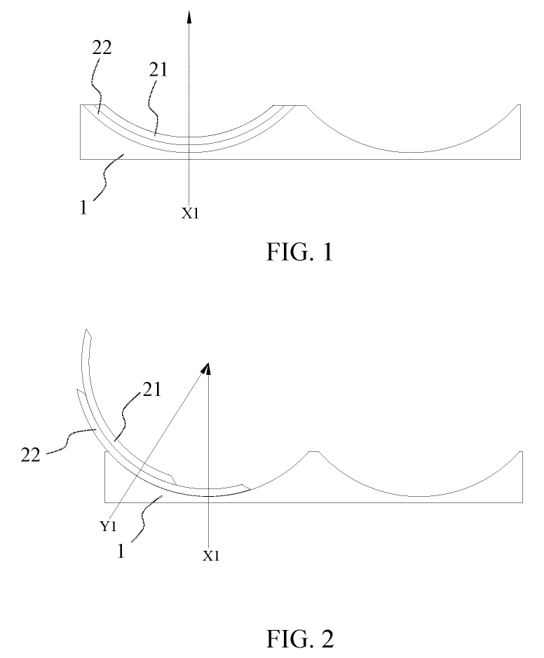

In one embodiment, as shown in FIG. 1, the connection mechanism includes a connection body 1 and a first rotation arm. The first rotation arm may include a first rotation sub arm 21 and a second rotation sub arm 22. The connection mechanism may at least have a first state. When the connection mechanism is in the first state, the first body and the second body may be unfolded relative to each other. The connection body 1, the first rotation sub arm 21, and the second rotation sub arm 22 may overlap in a first direction X1, where the first direction X1 is perpendicular to the bottom surface of the connection body 1. When the connection mechanism is in a first state, the connection body 1, the first rotation sub arm 21, and the second rotation sub arm 22 may overlap in the first direction X1, reducing the width of the connection mechanism. After the first body and the second body are connected to the connection mechanism, the distance between the first body and the second body in the width direction may be reduced, thereby making the first body and the second body thinner. The first direction, and the second, third, and fourth directions described below, are also referred to as first, second, third, and fourth lines, respectively. Two components overlapping in one of the directions may mean the two components overlapping along one of the lines. For example, when the connection mechanism is in the first state, the connection body 1, the first rotation sub arm 21, and the second rotation sub arm 22 may overlap along the first line.

In one embodiment, as shown in FIG. 1, the connection mechanism includes a connection body 1 and a first rotation arm. The first rotation arm may include a first rotation sub arm 21 and a second rotation sub arm 22. The connection mechanism may have a first state. When the connection mechanism is in the first state, the first body and the second body may be unfolded relative to each other. The connection body 1, the first rotation sub arm 21, and the second rotation sub arm 22 may overlap in the first direction X1. When the connection mechanism is in the first state, the first body and the second body may be unfolded relative to each other. As shown in FIG. 2, the connection mechanism also has a second state. When the connection mechanism is in the second state, the connection body 1, the first rotation sub arm 21, and the second rotation sub arm 22 may overlap in a second direction Y1. When the connection mechanism is in the second state, the first body and the second body may be folded relative to each other. The second direction Y1 may be different from the first direction X1. The second direction Y1 may be a direction in which the first direction X1 is rotated about the rotation center of the first direction X1 by a predetermined angle in a direction away from the centerline of the connection body 1. As shown in FIG. 2, the first rotation arm is located on the left side of the connection body 1, and the second direction Y1 is the direction in which the first direction X1 is rotated clockwise about the rotation center by a predetermined angle. When the connection mechanism is in the first state, the overlapping portion between the first rotation sub arm 21 and the second rotation sub arm 22 may be the first overlapping portion. When the connection mechanism is in the second state, the overlapping portion between the first rotation sub arm 21 and the second rotation sub arm 22 may be the second overlapping portion. The first overlapping portion may be larger than the second overlapping portion, meaning that in the second state, there is still an overlap between the first rotation sub arm 21, the second rotation sub arm 22, and the connection body 1, thereby improving the stability of the connection mechanism.

In a conventional hinge mechanism, there is only one rotation arm. When the overlap between the rotation arm and the rotation base is to be maintained, the width of the rotation base needs to be increased. When the width of the rotation base is narrowed, when the first body and the second body are folded, the rotation arm of the hinge mechanism will detach from the rotation base. Consistent with the present disclosure, the first rotation sub arm 21 and the second rotation sub arm 22 may have a first engagement area, and the second rotation sub arm 22 and the connection body 1 may have a second engagement area. There may be the second overlapping portion between the first rotation sub arm 21, the second rotation sub arm 22 and the connection body 1, such that the first engagement area and the second engagement area remain large enough to improve the stability of the connection mechanism. On the other hand, the overall structure of the first rotation arm including the first rotation sub arm 21 and the second rotation sub arm 22 may increase the engagement area with the connection body 1, thereby improving the stability of the connection mechanism. Therefore, the connection mechanism provided by the disclosure may make the width of the connection mechanism smaller, and also improve the stability of the connection mechanism.

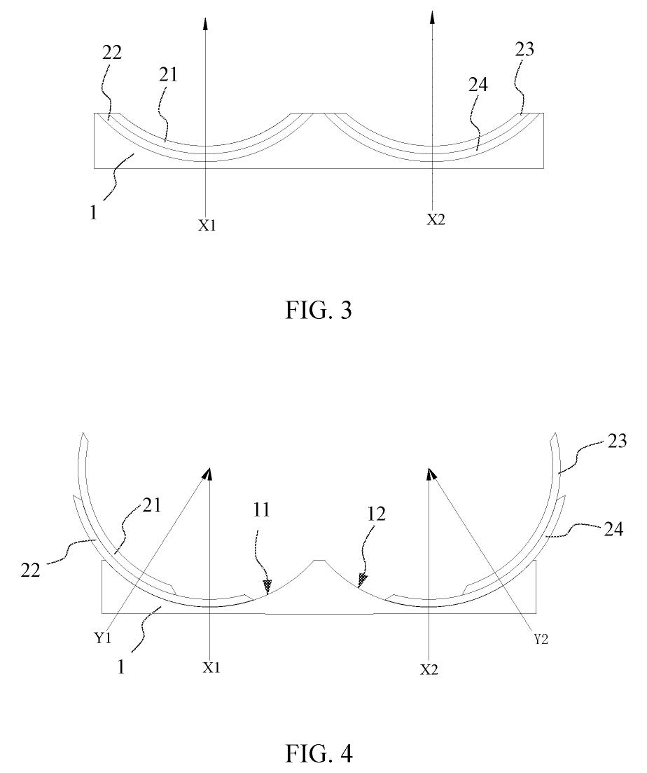

In one embodiment, as shown in FIG. 3, the connection mechanism includes a connection body 1, a first rotation arm, and a second rotation arm. The first rotation arm includes a first rotation sub arm 21 and a second rotation sub arm 22. The second rotation arm is symmetrically arranged with respect to the first rotation arm, and the second rotation arm includes a third rotation sub arm 23 and a fourth rotation sub arm 24. The connection mechanism at least has a first state. When the connection mechanism is in the first state, the connection body 1, the first rotation sub arm 21 and the second rotation sub arm 22 may overlap in the first direction X1. The connection body 1, the third rotation sub arm 23 and the fourth rotation sub arm 24 may overlap in a third direction X2. The first direction X1 and the third direction X2 may both be perpendicular to the bottom surface of the connection body 1. The first direction X1 may be parallel to the third direction X2. The connection body 1, the first rotation sub arm 21 and the second rotation sub arm 22 may overlap in the first direction X1. The connection body 1, the third rotation sub arm 23 and the fourth rotation sub arm 24 may overlap in the third direction X2. Therefore, the width of the connection mechanism may be smaller. After the first body and the second body are connected to the connection mechanism, the distance between the first body and the second body in the width direction may be reduced, such that the first body and the second body may be made thinner.

In one embodiment, as shown in FIG. 3 and FIG. 4, the connection mechanism includes a connection body 1, a first rotation arm, and a second rotation arm. The first rotation arm includes a first rotation sub arm 21 and a second rotation sub arm 22. The second rotation arm includes a third rotation sub arm 23 and a fourth rotation sub arm 24. The connection mechanism has a first state and a second state. When the connection mechanism is in the first state, the connection body 1, the first rotation sub arm 21, and the second rotation sub arm 22 may overlap in a first direction X1, and the connection body 1, the third rotation sub arm 23, and the fourth rotation sub arm 24 may overlap in a third direction X2. When the connection mechanism is in the second state, the connection body 1, the first rotation sub arm 21, and the second rotation sub arm 22 may overlap in a second direction Y1, and the connection body 1, the third rotation sub arm 23, and the fourth rotation sub arm 24 may overlap in a fourth direction Y2. The second direction Y1 is the direction in which the first direction X1 is rotated by a predetermined angle from the center of rotation of the first direction X1 in a direction away from the centerline of the connection body 1. The fourth direction Y2 is the direction in which the third direction X2 is rotated by a predetermined angle from the center of rotation of the third direction X2 in a direction away from the centerline of the connection body 1.

As shown in FIG. 4, the first rotation arm is located on the left side of the connection body 1, and the second rotation arm is located on the right side of the connection body 1. The second direction Y1 is the direction of clockwise rotation of the first direction X1 around the rotation center by a preset angle, and the fourth direction Y2 is the direction of counterclockwise rotation of the third direction X2 by a preset angle. When the connection mechanism is in the first state, the overlapping portion between the first rotation sub arm 21 and the second rotation sub arm 22 is the first overlapping portion, and the overlapping portion between the third rotation sub arm 23 and the fourth rotation sub arm 24 is the third portion. When the connection mechanism is in the second state, the overlapping portion between the first rotation sub arm 21 and the second rotation sub arm 22 is the second overlapping portion, and the overlapping portion between the third rotation sub arm 23 and the fourth rotation sub arm 24 is the fourth portion. The first overlapping portion is larger than the second overlapping portion, and the third overlapping portion is larger than the fourth overlapping portion. That is, when the connection mechanism is in the second state, there is still overlap between the first rotation sub arm 21, the second rotation sub arm 22, and the connection body 1, and there is still overlap between the third rotation sub arm 23, the fourth rotation sub arm 24, and the connection body 1, thereby improving the stability of the connection mechanism.

There may be the second overlapping portion between the first rotation sub arm 21, the second rotation sub arm 22 and the connection body 1, such that the engagement areas between the second rotation sub arm 22 respectively with the first rotation sub arm 21 and the connection body 1 are kept sufficiently large. There may be a fourth overlapping portion between the third rotation sub arm 23, the fourth rotation sub arm 24 and the connection body 1, such that the engagement areas between the fourth rotation sub arm 24 respectively with the third rotation sub arm 23 and the connection body 1 are kept sufficiently large, thereby improving the stability of the connection mechanism. The engagement area between the connection body 1 and the overall structure of the first rotation arm including the first rotation sub arm 21 and the second rotation sub arm 22 may be increased, and the engagement area between the connection body 1 and the overall structure of the second rotation arm including the third rotation sub arm 23 and the fourth rotation sub arm 24 may be increased, thereby improving the stability of the connection mechanism. Therefore, the connection mechanism provided by this embodiment, on the one hand, may make the width of the connection mechanism smaller, and on the other hand, may improve the stability of the connection mechanism.

In one embodiment, the connection mechanism may have a second state. The connection mechanism may include a second rotation arm arranged symmetrically with respect to the first rotation arm. The second rotation arm may include a third rotation sub arm 23 and a fourth rotation sub arm 24. When the connection mechanism is in the first state, the first rotation sub arm 21 may be closed with respect to the second rotation sub arm 22, and the third rotation sub arm 23 may be closed with respect to the fourth rotation sub arm 24, such that the surface formed by the first rotation sub arm 21 and the second rotation sub arm 22 and the surface formed by the third rotation sub arm 23 and the fourth rotation sub arm 24 may be coplanar. The surface formed by the first rotation sub arm 21 and the second rotation sub arm 22 and the surface formed by the third rotation sub arm 23 and the fourth rotation sub arm 24 may be coplanar, forming a flat support surface. When the flexible screen is attached to the first body and the second body, the surfaces formed by the closed first rotation sub arm 21 and second rotation sub arm 22, and the closed third rotation sub arm 23 and fourth rotation sub arm 24 may support the flexible screen, improving its stability.

When the connection mechanism is in the second state, the first rotation sub arm 21 and the second rotation sub arm 22 may open relative to each other, and the third sub-rotation arm 23 and the fourth sub-rotation arm 24 may open relative to each other. In this disclosure, two components “opening relative to each other” means they move, e.g., rotate, relative to each other to “open” or “expand” to a larger area, such as the first rotation sub arm 21 and the second rotation sub arm 22 moving relative to each other to change from the state shown in FIG. 1 to the state shown in FIG. 2. For example, the first rotation sub arm 21 may move relative to the second rotation sub arm 22 in a first rotational direction, while the third rotation sub arm 23 may move relative to the fourth rotation sub arm 24 in a second rotational direction. The first rotational direction may be different from the second rotational direction, allowing the first rotation sub arm to open away from the centerline of the connection body 1 relative to the second rotation sub arm and allowing the third rotation sub arm to open away from the centerline of the connection body 1 relative to the fourth rotation sub arm. As shown in FIG. 4, the first rotational direction is opposite to the second rotational direction in one embodiment. In FIG. 4, when the first rotation sub arm 21 and the second rotation sub arm 22 open, and the third rotation sub arm 23 and the fourth rotation sub arm 24 open, the first rotational direction is clockwise, while the second rotational direction is counterclockwise. After the first rotation sub arm 21 and the second rotation sub arm 22 open relative to each other, and the third rotation sub arm 23 and the fourth rotation sub arm 24 open relative to each other, an accommodating space may be formed among the first rotation sub arm 21, the second rotation sub arm 22, the third rotation sub arm 23, and the fourth rotation sub arm 24.

When the flexible screen is installed on the first body and the second body, the surface formed by the first rotation sub arm 21 extending relative to the second rotation sub arm 22 and the surface formed by the third rotation sub arm 23 extending relative to the fourth rotation sub arm 24 may enclose the accommodation space for the screen. The first rotation sub arm 21, the second rotation sub arm 22, the third rotation sub arm 23, and the fourth rotation sub arm 24 may support the flexible screen, allowing the flexible screen to be formed into a predetermined shape. Preferably, in one embodiment, the surface formed by the first rotation sub arm 21 extending relative to the second rotation sub arm 22 and the surface formed by the third rotation sub arm 23 extending relative to the fourth rotation sub arm 24 may enclose the accommodation space for the screen, allowing the flexible screen to form a teardrop shape.

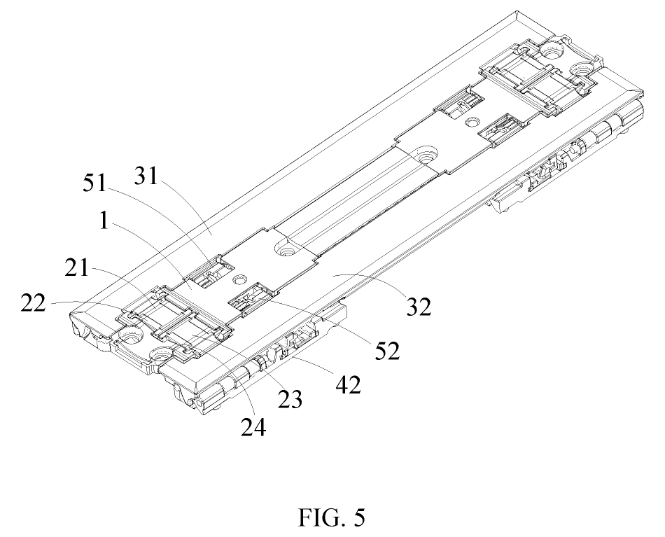

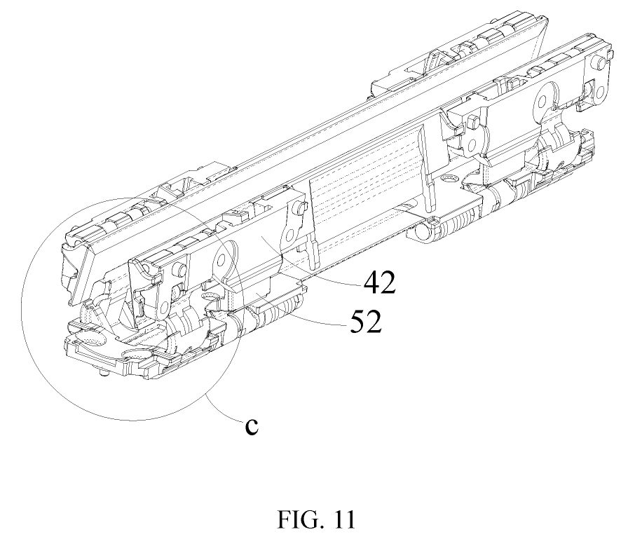

In one embodiment, as shown in FIG. 5 and FIG. 11, the electronic device further includes a first plate 31, a second plate 32, a first rotation arm, and a second rotation arm. The first rotation arm may be used to connect the first plate 31, and the second rotation arm may be used to connect the second plate 32. When the connection mechanism is in the first state, the first plate 31, the second plate 32, the surface formed by the first rotation sub arm 21 and the second rotation sub arm 22, and the surface formed by the third rotation sub arm 23 and the fourth rotation sub arm 24, may be coplanar. The first plate 31, the second plate 32, the surface formed by the first rotation sub arm 21 and the second rotation sub arm 22, and the surface formed by the third rotation sub arm 23 and the fourth rotation sub arm 24, may form a flat support surface. When the flexible screen is placed between the first body and the second body, the first plate 31 and the second plate 32 may support the flexible screen. The first plate 31 and the second plate 32 may cooperate with the connection mechanism to form the support surface for the flexible screen into a target shape. The first and second plates 31, 32, the surface formed by the closed first and second rotation sub arms 21, 22, and the surface formed by the closed third and fourth rotation sub arms 23, 24 are coplanar, supporting the flexible screen and improving its stability.

When the connection mechanism is in the second state, the first rotation sub ram 21 and the second rotation sub arm 22 may open in the first rotational direction, driving the first plate 31, and the third rotation sub arm 23 and the fourth rotation sub arm 24 may open in the second rotational direction, driving the second plate 32. The first and second rotational directions may be different. The first plate 31 and the second plate 32 may face each other at a target angle, forming the accommodation space with the connection body 1 of the connection mechanism. That is, the accommodation space may be formed between the first plate 31 and the second plate 32, the first rotation sub arm 21 and the second rotation sub arm 22, the third rotation sub arm 23 and the fourth rotation sub arm 24, and the connection body 1. When the flexible screen is placed between the first body and the second body, the first plate 31 and the second plate 32, and the connection body 1 of the connection mechanism may support the flexible screen, allowing it to form a predetermined shape. Preferably, in one embodiment, the surface formed by the first rotation sub arm 21 opening relative to the second rotation sub arm 22 and the surface formed by the third rotation sub arm 23 opening relative to the fourth rotation sub arm 24 may enclose the accommodation space for the screen, such that the flexible screen is able to form a water drop shape.

In one embodiment, the electronic device may also include a deformable display screen. A first part of the display screen may be connected to the first surface of the first body, and a second part of the display screen may be connected to the second surface of the second body. The first body may be in a first attitude with the second body through the connection mechanism, and the connection mechanism may be in a first state. The first body may be in a second attitude with the second body through the connection mechanism, and the connection mechanism may be in a second state.

When the first body and the second body are in the first attitude, the first body and the second body may be unfolded relative to each other, the connection mechanism may be in the first state. In the first attitude, the connection body 1, the first rotation sub arm 21 and the second rotation sub arm 22 may overlap in the first direction X1, the connection body 1, and the third rotation sub arm 23 and the fourth rotation sub arm 24 may overlap in the third direction X2. The first surface of the first body, the second surface of the second body, the first plate 31, the second plate 32, the surface formed by the first rotation sub arm 21 and the second rotation sub arm 22, and the surface formed by the third rotation sub arm 23 and the fourth rotation sub arm 24 may be coplanar, which may support the flexible screen, make the flexible screen a flat plane, and improve the stability of the flexible screen.

When the first body and the second body are in the second attitude, the first body and the second body may be folded relative to each other, and the connection mechanism may be in the second state. Therefore, the first surface of the first body and the second surface of the second body may be closed, the first rotation sub arm 21 and the second rotation sub arm 22 may open relative to each other, the third rotation sub arm 23 and the fourth rotation sub arm 24 may open relative to each other, and the first plate 31 may be opposite to the second plate 32. An accommodation space may be formed between the first and second plates 31 and 32, the first and second rotation sub arms 21 and 22, the third and fourth rotation sub arms 23 and 24, and the connection body 1. The first and second plates 31 and 32, and the connection body 1 of the connection mechanism may support the flexible screen, allowing the flexible screen to form a predetermined shape. Preferably, in one embodiment, the first and second plates 31 and 32, the surface formed by the first rotation sub arm 21 relative to the second rotation sub arm 22, and the surface formed by the third rotation sub arm 23 relative to the fourth rotation sub arm 24, may enclose the accommodation space for the screen, allowing the flexible screen to form a teardrop shape.

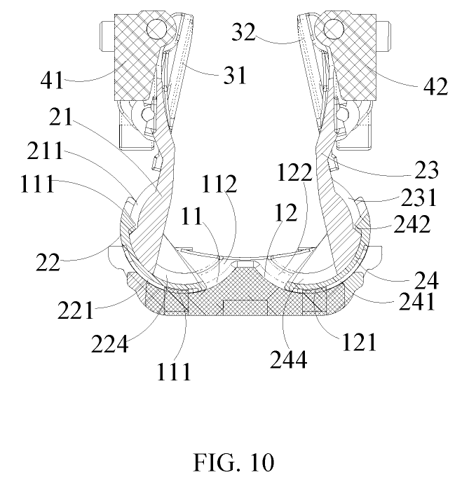

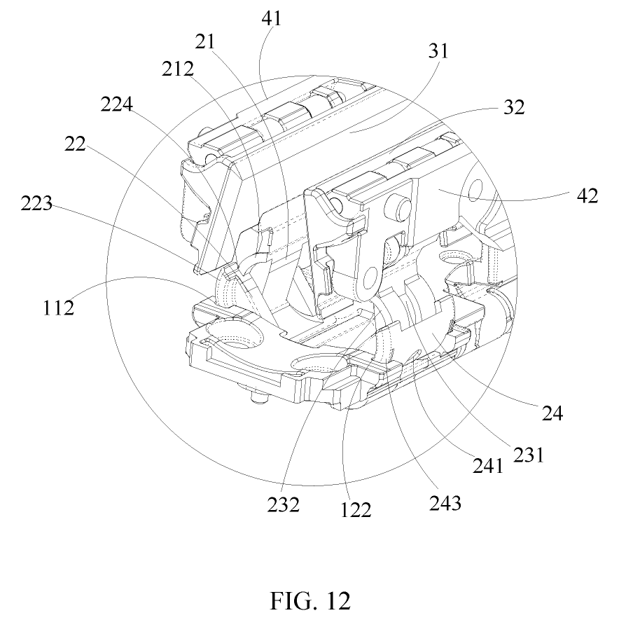

In one embodiment, as shown in FIG. 4 in conjunction with FIG. 10, FIG. 11 and FIG. 12, the connection body 1 includes a first arcuate groove and a second arcuate groove. The first arcuate groove 11 may be used to accommodate at least the closed first rotation sub arm 21 and the second rotation sub arm 22. The center point of the first arc of the first arcuate groove 11 may lie in the first direction X1, and the first point of the first arc may lie in the second direction Y1. The first point may be a point on one side of the first arc along the first rotational direction from the center point of the first arc. The first point may be a point where the first tangent of the first arc lies in the second direction Y1, and the second direction Y1 may be perpendicular to the first tangent. The first rotation sub arm 21, the second rotation sub arm 22, and the connection body 1 may have overlapping portions, allowing the second rotation sub arm 22 to have a larger engagement area with the first rotation sub arm 21 and the first arcuate groove 11, respectively, thereby improving the stability of the connection mechanism. On the other hand, the overall engagement area between the first rotation sub arm 21 and the second rotation sub arm 22 and the connection body 1 may be increased, thereby improving the stability of the connection mechanism. Further, the first rotation sub arm 21 and the second rotation sub arm 22 may open relative to each other to form a space of the desired shape.

The second arcuate groove 12 may be used to accommodate at least the closed third rotation sub arm 23 and the fourth rotation sub arm 24. The center point of the second arc of the second arcuate groove 12 lies in the third direction X2, and the second point of the second arc lies in the fourth direction Y2. The second point may be a point on the side of the second rotational direction from the center point of the first arc. The second point may be a point where the second tangent of the second arc lies in the fourth direction Y2, and the fourth direction Y2 may be perpendicular to the first tangent. There may be an overlapping part among the third rotation sub arm 23, the fourth rotation sub arm 24 and the connection body 1, and the fourth rotation sub arm 24 may have a large engagement area with the third rotation sub arm 23 and the second arcuate groove 12 respectively, thereby improving the stability of the connection mechanism. On the other hand, the overall structure of the second rotation arm including the third rotation sub arm 23 and the fourth rotation sub arm 24 may have a larger engagement area with the connection body 1, thereby improving the stability of the connection mechanism. Further, the third rotation sub arm 23 and the fourth rotation sub arm 24 may open relative to each other to form a space of the target shape.

In one embodiment, as shown in FIG. 10, FIG. 11, and FIG. 12, the first arcuate groove 11 is provided with a first stopper 111, and the second rotation sub arm 22 is provided with a first limit groove 221. The first stopper 111 is provided in the first limit groove 221; the second rotation sub arm 22 is provided with a second stopper 222, the first rotation sub arm 21 is provided with a second limit groove 211, and the second stopper 222 is provided in the second limit groove 211. The first stopper 111 may be used to limit the rotation angle of the second rotation sub arm 22, and the second stopper 222 may be used to limit the rotation angle of the first rotation sub arm 21, such that the connection body 1, the first rotation sub arm 21 and the second rotation sub arm 22 overlap in the second direction Y1 when the connection mechanism is in the second state. Therefore, the first rotation sub arm 21 and the second rotation sub arm 22 may have a first engagement area, and the second rotation sub arm 22 and the connection body 1 may have a second engagement area. There may be a second overlapping part between the first rotation sub arm 21, the second rotation sub arm 22 and the connection body 1, such that the first engagement area and the second engagement area remain large enough, thereby improving the stability of the connection mechanism. Also, the overall structure of the first rotation arm including the first rotation sub arm 21 and the second rotation sub arm 22 may have an increased engagement area with the connection body 1, thereby improving the stability of the connection mechanism.

The second arcuate groove 12 may be provided with a third stopper 121, and the fourth rotation sub arm 24 may be provided with a third limit groove 241. The third stopper 121 may be provided at the third limit groove 241. The fourth rotation sub arm 24 may be provided with a fourth stopper 242. The third rotation sub arm 23 may be provided with a fourth limit groove 231. The fourth stopper 242 may be provided at the fourth limit groove 231. The third stopper 121 may be used to limit the rotation angle of the fourth rotation sub arm 24, and the fourth stopper 242 may be used to limit the rotation angle of the third rotation sub arm 23. When the connection mechanism is in the second state, the connection body 1, the third rotation sub arm 23, and the fourth rotation sub arm 24 may overlap in the fourth direction Y2, allowing the third rotation sub arm 23 and the fourth rotation sub arm 24 to have a third bonding area, and the fourth rotation sub arm 24 and the connection body 1 to have a fourth bonding area. There may be a third overlapping part between the third rotation sub arm 23, the fourth rotation sub arm 24 and the connection body 1, such that the third bonding area and the fourth bonding area remain large enough, thereby improving the stability of the connection mechanism. Further, the overall structure of the second rotation arm including the third rotation sub arm 23 and the fourth rotation sub arm 24 may increase the bonding area with the connection body 1, thereby improving the stability of the connection mechanism.

In one embodiment, the first arc-shaped groove 11 may include a first arc surface, and the first arc surface may be provided with a first stop 111. The second rotation sub arm 22 may include a first mating surface facing the first arc surface, the first mating surface may be provided with a first limit groove 221, and the first stopper 111 may be provided in the first limit groove 221. The second rotation sub arm 22 may be provided with a second arc surface, and the second arc surface may be provided with a second stopper 222. The first rotation sub arm 21 may include a second mating surface facing the second arc surface, the second mating surface may be provided with a second limit groove 211, and the second stopper 222 may be provided in the second limit groove 211. The first stopper 111 may be used to limit the rotation angle of the second rotation sub arm 22, and the second stopper 222 may be used to limit the rotation angle of the first rotation sub arm 21, such that the connection body 1, the first rotation sub arm 21 and the second rotation sub arm 22 overlap in the second direction Y1 when the connection mechanism is in the second state.

The second arc-shaped groove 12 may include a third arc surface, and the third arc surface may be provided with a third stopper 121. The fourth rotation sub arm 24 may include a third mating surface facing the third arc surface, and the third mating surface may be provided with a third limit groove 241. The third stopper 121 may be arranged in the third limit groove 241. The fourth rotation sub arm 24 may be provided with a fourth arc surface, and the fourth arc surface may be provided with a fourth stopper 242. The third rotation sub arm 23 may include a fourth mating surface facing the fourth arc surface, and the fourth mating surface may be provided with a fourth limit groove 231. The fourth stopper 242 may be arranged in the fourth limit groove 231. The third stopper 121 may be used to limit the rotation angle of the fourth rotation sub arm 24, and the fourth stopper 242 may be used to limit the rotation angle of the third rotation sub arm 23, such that the connection body 1, the third rotation sub arm 23 and the fourth rotation sub arm 24 overlap in the fourth direction Y2 when the connection mechanism is in the second state.

In one embodiment, the sidewall of the first arcuate groove 11 may be provided with a first track groove 112, and the second rotation sub arm 22 may be provided with a first movable member 223. The first movable member 223 may be provided at the first track groove 112 and may move along the path of the first track groove 112. Correspondingly, the second rotation sub arm 22 and the connection body 1 may overlap in the first direction X1 when the connection mechanism is in the first state, and the second rotation sub arm 22 and the connection body 1 may overlap in the second direction Y1 when the connection mechanism is in the second state.

The second rotation sub arm 22 may be provided with a second track groove 224, and the first rotation sub arm 21 may be provided with a second movable member 212. The second movable member 212 may be provided at the second track groove 224 and may move along the path of the second track groove 224. Therefore, the first rotation sub arm 21 and the second rotation sub arm 22 may overlap in the first direction X1 when the connection mechanism is in the first state, and the first rotation sub arm 21 and the second rotation sub arm 22 may overlap in the second direction Y1 when the connection mechanism is in the second state. When the connection mechanism changes between the first and second states, the connection body 1, the first rotation sub arm 21, and the second rotation sub arm 22 may always overlap, thereby improving the stability of the connection mechanism. Further, the overall structure of the first rotation arm including the first rotation sub arm 21 and the second rotation sub arm 22, may increase the engagement area with the connection body 1, thereby improving the stability of the connection mechanism.

The sidewall of the second arcuate groove 12 may be provided with a third track groove 122, and the fourth rotation sub arm 24 may be provided with a third movable member 243. The third movable member 243 may be provided at the third track groove 122 and may be movable along the path of the third track groove 122. This may allow the fourth rotation sub arm 24 to overlap with the connection body 1 in the third direction X2 when the connection mechanism is in the first state, and to overlap with the connection body 1 in the fourth direction Y2 when the connection mechanism is in the second state.

The fourth rotation sub arm 24 may be provided with a fourth track groove 244, and the third rotation sub arm 23 may be provided with a fourth movable member 232. The fourth movable member 232 may be provided at the fourth track groove 244 and may move along the path of the fourth track groove 244. This may allow the third rotation sub arm 23 and the fourth rotation sub arm 24 to overlap in the third direction X2 when the connection mechanism is in the first state. When the connection mechanism is in the second state, the third rotation sub arm 23 and the fourth rotation sub arm 24 may overlap in the second direction, Y1. When the connection mechanism changes between the first and second states, the connection body 1, the third rotation sub arm 23, and the fourth rotation sub arm 24 may always overlap, improving the stability of the connection mechanism. Further, the overall structure of the second rotation arm, formed by the third rotation sub arm 23 and the fourth rotation sub arm 24, may increase the engagement area with the connection body 1, further enhancing the stability of the connection mechanism.

The present disclosure also provides a connection mechanism for use in an electronic device, such as a mobile terminal, particularly one with foldable screens, such as a mobile phone, a PDA, a laptop computer, or a tablet computer. The connection mechanism may include a connection body 1 and a first rotation arm. The first rotation arm may include a first rotation sub arm 21 and a second rotation sub arm 22. The connection mechanism may at least have a first state. In the first state, the connection body 1, the first rotation sub arm 21, and the second rotation sub arm 22 may overlap in a first direction X1.

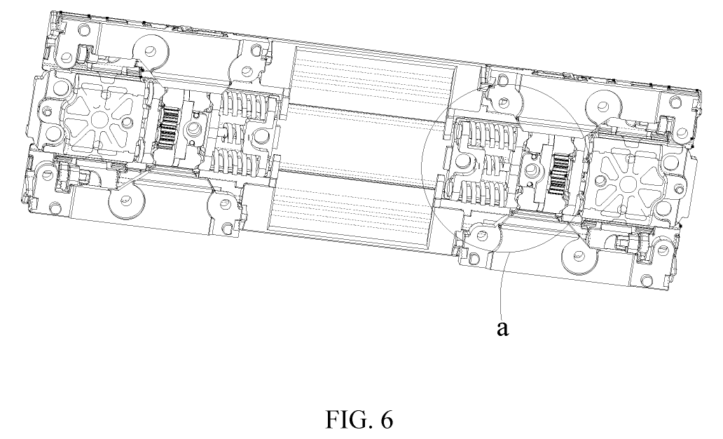

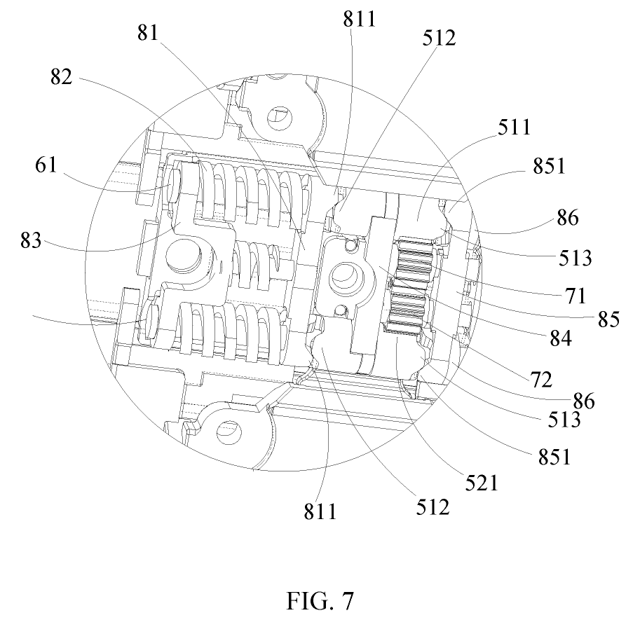

In one embodiment, as shown in FIG. 5, FIG. 6 and FIG. 7, the connection mechanism may include a fixation arm assembly, a torque assembly, and a track assembly.

The fixation arm assembly may include a first fixation arm 41 and a second fixation arm 42. The first fixation arm 41 may be used to securely connect to the first body of the electronic device, and the second fixation arm 42 may be used to securely connect to the second body of the electronic device.

The torque assembly may include a symmetrically arranged first rotation shaft 61 and a second rotation shaft 62, a synchronization assembly, a first torque arm 51, and a second torque arm 52. One end of the first torque arm 51 may be rotationally connected to the first rotation shaft 61, and the other end of the first torque arm 51 may be slidingly matched with the first fixation arm 41. One end of the second torque arm 52 may be rotationally connected to the second rotation shaft 62, and the other end of the second torque arm 52 may be slidingly matched with the second fixation arm 42. The synchronization assembly may be transmission-connected to the first torque arm 51 and the second torque arm 52, to realize synchronous reverse rotation between the first torque arm 51 and the second torque arm 52.

The track assembly may include a first rotation arm and a second rotation arm. One end of the first rotation arm may be rotationally connected to the connection body 1, and the other end may be rotationally connected to the first fixation arm 41. The second rotation arm may include one end rotationally connected to the connection body 1 and the other end rotationally connected to the second fixation arm 42.

When the first body and the second body are folded or unfolded relative to each other, for example, by applying a driving force to the first body, the first body may be connected to the first fixation arm 41, transmitting the force to the first fixation arm 41, which pushes the first torque arm 51. The synchronization assembly may link the first torque arm 51 and the second torque arm 52, to achieve synchronous opposite-direction movement. In other words, pushing one of the first torque arm 51 and the second torque arm 52 may cause the other to fold or unfold in the opposite direction.

When the first fixation arm 41 rotates with the first body and the second fixation arm 42 rotates with the second body, the first rotation arm 41 and the second rotation arm 42 may restrict the position of the first fixation arm 41 and the second rotation arm 42 during rotation, respectively. The first torsion arm 51 may slidably engage with the first fixation arm 41, allowing the first fixation arm 41 to adapt to the trajectory of the first rotation arm during unfolding or folding, ensuring that the first rotation arm remains in the appropriate position during unfolding or folding. The second torsion arm 52 may slidably engage with the second fixation arm 42, allowing the second fixation arm 42 to adapt to the unfolding or folding path of the second rotation arm, ensuring that the second fixation arm 42 remains in the appropriate position during unfolding or folding.

In one embodiment, the first rotation shaft 61 and the second rotation shaft 62 may both be mounted on the connection body 1 and arranged parallel to each other. The first body may be rotatably connected to the connection body 1 via the first rotation shaft 61, and the second body may be rotatably connected to the connection body 1 via the second rotation shaft 62, thereby enabling relative movement between the first body and the second body, thereby achieving folding and unfolding of the electronic device.

To enable synchronous relative movement between the first body and the second body, the first torque arm 51 may be provided with a first gear 511, which may be rotatably connected to the first rotation shaft 61. The second torque arm 52 may be provided with a second gear 521, which may be rotatably connected to the second rotation shaft 62. The synchronization assembly may enable meshing transmission between the first gear 511 and the second gear 521, resulting in opposite rotations of the first gear 511 and the second gear 521.

When a user applies a driving force to the first body, the driving force may cause the first body to rotate relative to the connection body 1. The first body, in turn, may drive the first torque arm 51 to rotate relative to the connection body 1. The first torque arm 51 may drive the first gear 511 to rotate relative to the connection body 1. Through the synchronization assembly, the first gear 511 may drive the second gear 521 to rotate relative to the connection body 1. The second gear 521 may drive the second drive gear 521 to rotate relative to the connection body 1. Ultimately, the second torque arm 52 may drive the second body to rotate relative to the connection body 1, thus facilitating operation. When the user applies a driving force to the second body, the force transmission direction may be reversed.

The synchronization assembly may include a third gear 71 and a fourth gear 72 meshing with each other. The third gear 71 may mesh with the first gear 511, and the fourth gear 72 may mesh with the second gear 521, enabling synchronized counter-rotating movement of the first body and the second body. The synchronization assembly may include an even number of meshing gears, with the gears on either side meshing with the first gear 511 and the second gear 521, respectively, to achieve synchronized counter-rotating movement of the first body and the second body.

To enable the electronic device to hover such that the first body and the second body are able to be relatively fixed within a preset angle, the connection mechanism may also include a damping component, which includes a movable member 81, an elastic member 82, and a first connection seat 83. The first rotation shaft 61 and the second rotation shaft 62 may be installed on the first connection seat 83. The movable member 81 may be able to move relative to the first connection seat 83 along the axial direction of the first rotation shaft 61. The elastic member 82 may be arranged between the movable member 81 and the first connection seat 83. The two ends of the elastic member 82 may be respectively abutted against the movable member 81 and the first connection seat 83. The elastic member 82 may apply an elastic force to the movable member 81 such that the movable member 81 moves in a direction away from the first connection seat 83 to abut against the first torque arm 51 and the second torque arm 52, thereby preventing the first torque arm 51 and the second torque arm 52 from rotating relative to the connection body 1, and utilizing the elastic force of the elastic member 82 to make the first body hover relative to the connection body 1.

In one embodiment, the movable member 81 may be provided with first cams 811, and the movable member 81 may be sleeved on the first rotation shaft 61 and the second rotation shaft 62. There may be two first cams 811, which are sleeved on the first rotation shaft 61 and the second rotation shaft 62 respectively, such that the first cams 811 are able to follow the axial movement of the movable member 81 relative to the first rotation shaft 61. Optionally, the first cams 811 may be fixedly connected to the movable member 81. The first torque arm 51 and the second torque arm 52 may both be provided with a second cam 512, and the first cams 811 and the second cams 512 may be abutted against each other, and the first cams 811 and the second cams 512 may be provided with abutting inclined surfaces. The abutting inclined surfaces may decompose the interaction force between the first cams 811 and the second cams 512 along the tangential direction of the second cams 512, thereby driving the second cams 512 to rotate, to realize the automatic opening and closing of the first body and the second body, that is, to provide torque.

When a user applies a driving force toward the first body, the driving force may drive the first torque arm 51 to rotate relative to the first rotation shaft 61. The first gear 511 may drive the second cams 512 to rotate relative to the first cam 811. The abutting inclined surfaces of the first cams 811 and the second cams 512 may interact, causing the first cams 811 to drive the movable member 81 to move toward the first connection seat 83 and elastically deform the elastic member 82. When the user’s driving force is removed, the elastic member 82 may apply an elastic force toward the movable member 81, causing the first cams 811 on the movable member 81 to abut against the second cams 512 on the first torque arm 51, thereby restricting the rotation of the second cams 512 and, in turn, the rotation of the first body relative to the connection body 1. At this point, the first body and the second body may be in relative suspension.

In one embodiment, the connection body 1 may be provided with a second connection seat 84, which may be fixedly connected to the connection body 1. The first rotation shaft 61 and the second rotation shaft 62 may both be inserted through the second connection seat 84. Both the first rotation shaft 61 and the second rotation shaft 62 may be movable along the circumferential direction of the first rotation shaft 61. The first gear 511 and second cams 512 of the first torque arm 51 may be respectively disposed at opposite ends of the first connection seat 83 along the first axial direction, preventing the first torque arm 51 from axially moving along the first rotation shaft 61. The second gear 521 and the second cams 512 of the second torque arm 52 may be respectively disposed at opposite ends of the first connection seat 83 along the second axial direction, preventing the second torque arm 52 from axially moving along the second rotation shaft 62.

The damping assembly may also include a fixing member 85, which may be sleeved on the first rotation shaft 61 and the second rotation shaft 62. Both the first rotation shaft 61 and the second rotation shaft 62 may be provided with positioning members 86, which prevent the fixing member 85 from axially moving along the first rotation shaft 61. The positioning members 86 may be snaps or positioning pins. The fixing member 85 may be provided with two third cams 851, one of which is mounted on the first rotation shaft 61 and the other on the second rotation shaft 62. Optionally, the third cams 851 may be fixedly connected to the fixing member 85.

Both the first torque arm 51 and the second torque arm 52 may be provided with fourth cams 513. The third cams 851 and the fourth cams 513 may abut against each other, and the third cams 851 and the fourth cams 513 may be provided with abutting inclined surfaces. The abutting inclined surfaces may decompose the interaction force between the third cams 851 and the fourth cams 513 along the tangent direction of the fourth cams 513, thereby driving the fourth cams 513 to rotate, achieving automatic opening and closing of the first body and the second body, thereby providing torque.

When a user applies a driving force toward the first body, the driving force may cause the first torque arm 51 to rotate relative to the first rotation shaft 61, which in turn causes the fourth cams 513 to rotate relative to the third cams 851. The abutting inclined surfaces of the third cams 851 and the fourth cams 513 may interact, causing the third cams 851 to drive the fixing member 85, the first rotation shaft 61, and the second rotation shaft 62 to move away from the first connection seat 83. The axial distance between the first connection seat 83 and the second connection seat 84 on the first rotation shaft 61 may decrease, and the movable member 81 may compress the elastic member 82, causing it to elastically deform. When the user’s driving force is removed, the elastic member 82 may apply an elastic force toward the movable member 81 and the first connection seat 83, causing the third cams 851 on the fixing member 85 to abut against the fourth cams 513 on the first torque arm 51, thereby limiting the rotation of the fourth cams 513 and, in turn, limiting the rotation of the first body relative to the connection body 1. At this point, the first body and the second body may be in relative suspension.

In one embodiment, when a user applies a driving force toward the first body, the first cams 811 and the second cams 512 may interact, and the third cams 851 and the fourth cams 513 may interact. The two sets of cams may act simultaneously, increasing the pressure on the elastic member 82. When the user’s driving force is removed, the elastic member 82 may apply an elastic force toward the movable member 81, causing the first cams 811 on the movable member 81 to abut against the second cams 512 on the first torque arm 51, thereby limiting the rotation of the second cams 512. The elastic member 82 may also apply an elastic force toward the movable member 81 and the first connection seat 83, causing the third cams 851 on the fixing member 85 to abut against the fourth cams 513 on the first torque arm 51, thereby limiting the rotation of the fourth cams 513. This, in turn, may limit the rotation of the first body relative to the connection body 1, reducing the possibility of shaking when the first body and the second body are hovering relative to each other.

In some embodiments, the first rotation arm may include a first rotation sub arm 21 and a second rotation sub arm 22. The second rotation sub arm 22 may be rotationally connected to the first rotation sub arm 21 and the connection body 1, respectively. The first rotation sub arm 21 may be rotationally connected to the first fixation arm 41. The second rotation arm may include a third rotation sub arm 23 and a fourth rotation sub arm 24. The fourth rotation sub arm 24 may be rotationally connected to the third rotation sub arm 23 and the connection body 1, respectively. The third rotation sub arm 23 may be rotationally connected to the second fixation arm 42. When the connection mechanism is in the first state, the connection body 1, the first rotation sub arm 21, and the second rotation sub arm 22 may overlap in the first direction X1, and the connection body 1, the third rotation sub arm 23, and the fourth rotation sub arm 24 may overlap in the third direction X2. This may reduce the width of the connection mechanism. When the connection mechanism is in the second state, the first rotation sub arm 21, the second rotation sub arm 22, and the connection body 1 may still have overlapping portions, and the third rotation sub arm 23, the fourth rotation sub arm 24 may still have overlapping portions with the connection body 1, thereby improving the stability of the connection mechanism.

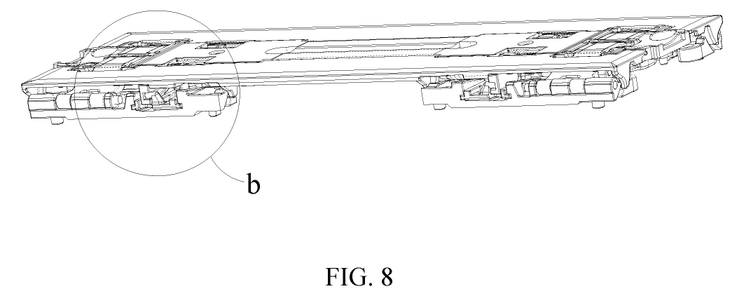

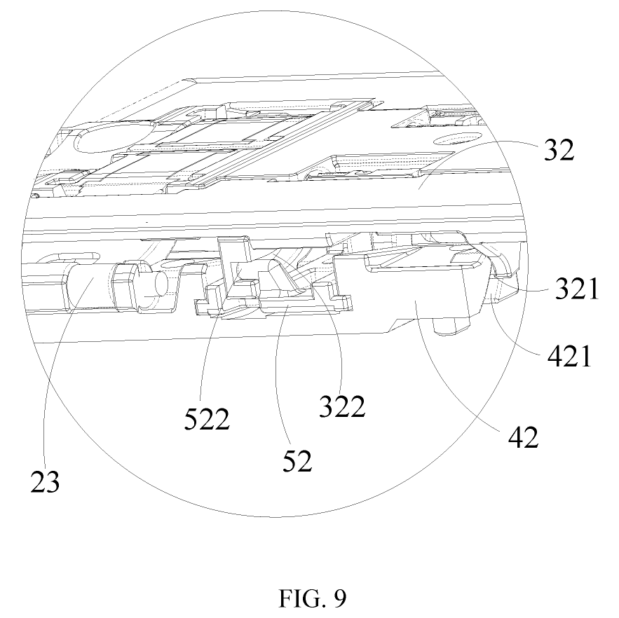

As shown in FIG. 8 and FIG. 9, the first plate 31 may be rotationally connected to the first fixation arm 41, and the first plate 31 and the first torque arm 51 may be engaged via a pin groove. The second plate 32 may be rotationally connected to the second fixation arm 42, and the second plate 32 and the second torque arm 52 may be engaged via a pin groove. Optionally, the second plate 32 may be provided with a fifth movable member 321, and the second fixation arm 42 may be provided with a fifth track groove 421. The second plate 32 and the second torque arm 52 may be rotationally connected, and the fifth movable member 321 may be provided at the fifth track groove 421. Optionally, the second plate 32 may be provided with a slide groove 322, and the second torque arm 52 may be provided with a guide post 522. The guide post 522 may be slidably provided at the slide groove 322. The first plate 31 and the second plate 32 may support the flexible screen, and the first plate 31 and the second plate 32 may cooperate with the connection mechanism to enable the support surface used to support the flexible screen to form a target shape.

It should be understood that the various forms of the processes shown above can be used to reorder, add, or delete steps. For example, the steps described in this disclosure can be performed in parallel, sequentially, or in a different order, as long as the desired results of the technical solutions disclosed in this disclosure can be achieved. This is not a limitation herein.

The terms “first,” “second,” and so on, are used for descriptive purposes only and should not be understood as indicating or implying relative importance or implicitly specifying the number of technical features being referred to. Thus, a feature defined as “first” or “second” may explicitly or implicitly include at least one such feature. Throughout the present disclosure, “plurality” means two or more, unless otherwise specifically defined.

The above describes in detail a plurality of embodiments of the present disclosure, but the present disclosure is not limited to these specific embodiments. Those skilled in the art can make various variations and modifications based on the concept of the present disclosure, and these variations and modifications shall fall within the scope of the present disclosure.

What is claimed is:

1. An electronic device comprising:
a first body;
a second body; and
a connection mechanism connecting the first body to the second body and including:
a connection body; and
a rotation arm including a first rotation sub arm and a second rotation sub arm;
wherein the connection mechanism has a state in which the connection body, the first rotation sub arm, and the second rotation sub arm overlap along a line.

2. The electronic device according to claim 1, wherein:
the state is a first state and the line is a first line;
the connection mechanism further has a second state in which the connection body, the first rotation sub arm, and the second rotation sub arm overlap along a second line different from the first line; and
a first overlapping portion between the first rotation sub arm and the second rotation sub arm when the connection mechanism is in the first state is larger than a second overlapping portion between the first rotation sub arm and the second rotation sub arm when the connection mechanism is in the second state.

3. The electronic device according to claim 1, wherein:
the rotation arm is a first rotation arm and the line is a first line;
the connection mechanism further includes a second rotation arm symmetrically arranged with respect to the first rotation arm and including a third rotation sub arm and a fourth rotation sub arm; and
when the connection mechanism is in the state, the connection body, the third rotation sub arm, and the fourth rotation sub arm overlap along a second line parallel to the first line.

4. The electronic device according to claim 1, wherein:
the rotation arm is a first rotation arm and the state is a first state;
the connection mechanism further has a second state;
the connection mechanism further includes a second rotation arm symmetrically arranged with respect to the first rotation arm and including a third rotation sub arm and a fourth rotation sub arm;
when the connection mechanism is in the first state, the first rotation sub arm is closed with respect to the second rotation sub arm, the third rotation sub arm is closed with respect to the fourth rotation sub arm, and a surface formed by the first rotation sub arm and the second rotation sub arm is coplanar with a surface formed by the third rotation sub arm and the fourth rotation sub arm; and
when the connection mechanism is in the second state, the first rotation sub arm is opened in a first rotational direction with respect to the second rotation sub arm, and the third rotation sub arm is opened in a second rotational direction with respect to the fourth rotation sub arm, the first rotational direction being different from the second rotational direction.

5. The electronic device according to claim 1, further comprising:
a first plate and a second plate;
wherein:
the rotation arm is a first rotation arm and the state is a first state;
the connection mechanism further has a second state;
the connection mechanism further includes a second rotation arm symmetrically arranged with respect to the first rotation arm and including a third rotation sub arm and a fourth rotation sub arm;
the first rotation arm is connected to the first plate and the second rotation arm is connected to the second plate;
when the connection mechanism is in the first state, the first plate, the second plate, a surface formed by the first rotation sub arm and the second rotation sub arm closed with respect to each other, and a surface formed by the third rotation sub arm and the fourth rotation sub arm closed with respect to each other, are coplanar; and
when the connection mechanism is in the second state, the first rotation sub arm and the second rotation sub arm are opened with respect to each other in a first rotational direction, the third rotation sub arm and the fourth rotation sub arm are opened with respect to each other in a second rotational direction different from the first rotational direction, and the first plate and the second plate are opposite to each other at a target angle and form an accommodation space together with the connection body.

6. The electronic device according to claim 1, further comprising:
a deformable display screen, a first portion of the display screen being connected to a first surface of the first body, and a second portion of the display screen being connected to a second surface of the second body.

7. The electronic device according to claim 1, wherein:
the state is a first state and the line is a first line;
the connection mechanism further has a second state in which the connection body, the first rotation sub arm, and the second rotation sub arm overlap along a second line different from the first line;
when the connection mechanism is in the first state, the first body and the second body are in a first attitude; and
when the connection mechanism is in the second state, the first body and the second body are in a second attitude.

8. The electronic device according to claim 1, wherein:
the rotation arm is a first rotation arm;
the connection mechanism further includes a second rotation arm symmetrically arranged with respect to the first rotation arm and including a third rotation sub arm and a fourth rotation sub arm; and
the connection body includes:
a first arcuate groove, configured to accommodate the first rotation sub arm and the second rotation sub arm when the first rotation sub arm and the second rotation sub arm are closed, the first rotation sub arm and the second rotation sub arm being configured to rotate along a first arc of the first arcuate groove away from a center point of the first arc in a direction away from a center point of the connection body; and
a second arcuate groove, configured to accommodate the third rotation sub arm and the fourth rotation sub arm when the third rotation sub arm and the fourth rotation sub arm are closed, the third rotation sub arm and the fourth rotation sub arm being configured to rotate along a second arc of the second arcuate groove away from a center point of the second arc in a direction away from the center point of the connection body.

9. The electronic device according to claim 8, wherein:
the state is a first state and the line is a first line;
the first arcuate groove is provided with a first stopper, the second rotation sub arm is provided with a first limit groove, and the first stopper is provided at the first limit groove;
the second rotation sub arm is provided with a second stopper, the first rotation sub arm is provided with a second limit groove, and the second stopper is provided at the second limit groove;
the first stopper is configured to limit a rotation angle of the second rotation sub arm, and the second stopper is configured to limit a rotation angle of the first rotation sub arm, such that the connection body, the first rotation sub arm, and the second rotation sub arm overlap along a second line different from the first line when the connection mechanism is in a second state;
when the connection mechanism is in the first state, the connection body, the third rotation sub arm, and the fourth rotation sum arm overlap along a third line parallel to the first line;
the second arcuate groove is provided with a third stopper, the fourth rotation sub arm is provided with a third limit groove, and the third stopper is provided at the third limit groove;
the fourth rotation sub arm is provided with a fourth stopper, the third rotation sub arm is provided with a fourth limit groove, and the fourth stopper is provided at the fourth limit groove; and
the third stopper is configured to limit a rotation angle of the fourth rotation sub arm, and the fourth stopper is configured to limit a rotation angle of the third rotation sub arm, such that the connection body, the third rotation sub arm, and the fourth rotation sub arm overlap along a fourth line different from the third line when the connection mechanism is in the second state.

10. The electronic device according to claim 1, wherein:
the rotation arm is a first rotation arm;
the connection mechanism further includes:
a first fixation arm fixedly connected to the first body;
a second fixation arm fixedly connected to the second body;
a first rotation shaft and a second rotation shaft symmetrically arranged with respect to each other;
a first torque arm, one end of the first torque arm being rotationally connected to the first rotation shaft and another end of the first torque arm slidingly engaging with the first fixation arm;
a second torque arm, one end of the second torque arm being rotationally connected to the second rotation shaft and another end of the second torque arm slidingly engaging with the second fixation arm;
a synchronization assembly transmission-connected to the first torque arm and the second torque arm to achieve synchronized counter-rotation of the first torque arm and the second torque arm; and
a second rotation arm, one end of the second rotation arm being rotationally connected to the connection body and another end of the second rotation arm being rotationally connected to the second fixation arm; and
one end of the first rotation arm is rotationally connected to the connection body and another end of the first rotation arm is rotationally connected to the first fixation arm.

11. A connection mechanism comprising:
a connection body; and
a rotation arm including a first rotation sub arm and a second rotation sub arm;
wherein the connection mechanism has a state in which the connection body, the first rotation sub arm, and the second rotation sub arm overlap in a direction .

12. The connection mechanism according to claim 11, wherein:
the state is a first state and the line is a first line;
the connection mechanism further has a second state in which the connection body, the first rotation sub arm, and the second rotation sub arm overlap along a second line different from the first line; and
a first overlapping portion between the first rotation sub arm and the second rotation sub arm when the connection mechanism is in the first state is larger than a second overlapping portion between the first rotation sub arm and the second rotation sub arm when the connection mechanism is in the second state.

13. The connection mechanism according to claim 11,
wherein the rotation arm is a first rotation arm and the line is a first line;
the connection mechanism further comprising:
a second rotation arm symmetrically arranged with respect to the first rotation arm and including a third rotation sub arm and a fourth rotation sub arm;
wherein when the connection mechanism is in the state, the connection body, the third rotation sub arm, and the fourth rotation sub arm overlap along a second line parallel to the first line.

14. The connection mechanism according to claim 11,
wherein the rotation arm is a first rotation arm and the state is a first state;
the connection mechanism further comprising:
a second rotation arm symmetrically arranged with respect to the first rotation arm and including a third rotation sub arm and a fourth rotation sub arm;
wherein:
when the connection mechanism is in the first state, the first rotation sub arm is closed with respect to the second rotation sub arm, the third rotation sub arm is closed with respect to the fourth rotation sub arm, and a surface formed by the first rotation sub arm and the second rotation sub arm is coplanar with a surface formed by the third rotation sub arm and the fourth rotation sub arm; and
the connection mechanism further has a second state in which the first rotation sub arm is opened in a first rotational direction with respect to the second rotation sub arm, and the third rotation sub arm is opened in a second rotational direction with respect to the fourth rotation sub arm, the first rotational direction being different from the second rotational direction.

15. The connection mechanism according to claim 11,
wherein:
the rotation arm is a first rotation arm and the state is a first state; and
the connection mechanism further has a second state;
the connection mechanism further comprising:
a second rotation arm symmetrically arranged with respect to the first rotation arm and including a third rotation sub arm and a fourth rotation sub arm;
wherein:
the first rotation arm is configured to be connected to a first plate of an electronic device and the second rotation arm is configured to be connected to a second plate of the electronic device;
when the connection mechanism is in the first state, the first plate, the second plate, a surface formed by the first rotation sub arm and the second rotation sub arm closed with respect to each other, and a surface formed by the third rotation sub arm and the fourth rotation sub arm closed with respect to each other, are coplanar; and
the connection mechanism further has a second state in which the first rotation sub arm and the second rotation sub arm are opened with respect to each other in a first rotational direction, the third rotation sub arm and the fourth rotation sub arm are opened with respect to each other in a second rotational direction different from the first rotational direction, and the first plate and the second plate are opposite to each other at a target angle and form an accommodation space together with the connection body.

16. The connection mechanism according to claim 11, wherein:
the state is a first state and the line is a first line; and
the connection mechanism further has a second state in which the connection body, the first rotation sub arm, and the second rotation sub arm overlap along a second line different from the first line.

17. The connection mechanism according to claim 11,
wherein the rotation arm is a first rotation arm;
the connection mechanism further comprising:
a second rotation arm symmetrically arranged with respect to the first rotation arm and including a third rotation sub arm and a fourth rotation sub arm;
wherein the connection body includes:
a first arcuate groove, configured to accommodate the first rotation sub arm and the second rotation sub arm when the first rotation sub arm and the second rotation sub arm are closed, the first rotation sub arm and the second rotation sub arm being configured to rotate along a first arc of the first arcuate groove away from a center point of the first arc in a direction away from a center point of the connection body; and
a second arcuate groove, configured to accommodate the third rotation sub arm and the fourth rotation sub arm when the third rotation sub arm and the fourth rotation sub arm are closed, the third rotation sub arm and the fourth rotation sub arm being configured to rotate along a second arc of the second arcuate groove away from a center point of the second arc in a direction away from the center point of the connection body.

18. The connection mechanism according to claim 17, wherein:
the state is a first state and the line is a first line;
the first arcuate groove is provided with a first stopper, the second rotation sub arm is provided with a first limit groove, and the first stopper is provided at the first limit groove;
the second rotation sub arm is provided with a second stopper, the first rotation sub arm is provided with a second limit groove, and the second stopper is provided at the second limit groove;
the first stopper is configured to limit a rotation angle of the second rotation sub arm, and the second stopper is configured to limit a rotation angle of the first rotation sub arm, such that the connection body, the first rotation sub arm, and the second rotation sub arm overlap along a second line different from the first line when the connection mechanism is in a second state;
when the connection mechanism is in the first state, the connection body, the third rotation sub arm, and the fourth rotation sum arm overlap along a third line parallel to the first line;
the second arcuate groove is provided with a third stopper, the fourth rotation sub arm is provided with a third limit groove, and the third stopper is provided at the third limit groove;
the fourth rotation sub arm is provided with a fourth stopper, the third rotation sub arm is provided with a fourth limit groove, and the fourth stopper is provided at the fourth limit groove; and
the third stopper is configured to limit a rotation angle of the fourth rotation sub arm, and the fourth stopper is configured to limit a rotation angle of the third rotation sub arm, such that the connection body, the third rotation sub arm, and the fourth rotation sub arm overlap along a fourth line different from the third line when the connection mechanism is in the second state.

19. The connection mechanism according to claim 11,
wherein the rotation arm is a first rotation arm;
the connection mechanism further comprising:
a first fixation arm configured to be fixedly connected to a first body of an electronic device;
a second fixation arm configured to be fixedly connected to a second body of the electronic device;
a first rotation shaft and a second rotation shaft symmetrically arranged with respect to each other;
a first torque arm, one end of the first torque arm being rotationally connected to the first rotation shaft and another end of the first torque arm slidingly engaging with the first fixation arm;
a second torque arm, one end of the second torque arm being rotationally connected to the second rotation shaft and another end of the second torque arm slidingly engaging with the second fixation arm;
a synchronization assembly transmission-connected to the first torque arm and the second torque arm to achieve synchronized counter-rotation of the first torque arm and the second torque arm; and
a second rotation arm, one end of the second rotation arm being rotationally connected to the connection body and another end of the second rotation arm being rotationally connected to the second fixation arm;
wherein one end of the first rotation arm is rotationally connected to the connection body and another end of the first rotation arm is rotationally connected to the first fixation arm.
